(19) United States
(12) Patent Application Publication
(10) Pub. No.: US 2012/0274866 A1
(43) Pub. Date: Nov. 1, 2012

(54) TELEVISION APPARATUS AND ELECTRONIC APPARATUS

(76) Inventor: KOJI TADA, Hamura-shi (JP)

(21) Appl. No.: 13/364,112

(22) Filed: Feb. 1, 2012

(30) Foreign Application Priority Data
Apr. 28, 2011 (JP) 2011-101676

(51) Int. Cl. H04N 5/64; H05K 5/00

(52) U.S. Cl. 348/836; 361/752; 348/E05.128

(57) ABSTRACT

In one embodiment, there is provided a television apparatus. The apparatus includes: an enclosure; a circuit board housed in the enclosure; and an electronic component mounted on the circuit board. The electronic component includes: a heating element that generates heat when current is supplied to the heating element; a housing that houses the heating element therein; an electrode provided on the housing; a bonding member provided on the housing such that a position of the bonding member does not overlap with a position of the electrode, wherein the housing is bonded onto the circuit board via the bonding member; and a protective member provided between the housing and the boding member to cover at least a partial region of the first surface of the housing, the protective member being configured to prevent he bonding member from entering into the housing when the heating element generates heat.

This application claims priority from Japanese Patent Application No. 2011-101676, filed on Apr. 28, 2011, the entire contents of which are hereby incorporated by reference.

### BACKGROUND

1. Field

Embodiments described herein relate to a television apparatus and an electronic apparatus.

2. Description of the Related Art

In the related art, there is known an electric apparatus which has an electronic component such as an inductor component and a board mounted with the electronic component and in which electrodes of the electronic component are soldered to the board by solders.

It is desired that stress on a component built in a television apparatus and an electronic apparatus is relaxed.

### BRIEF DESCRIPTION OF THE DRAWINGS

A general architecture that implements the various features of the invention will now be described with reference to the drawings. The drawings and the associated descriptions are provided to illustrate embodiments of the invention and not to limit the scope of the invention:

FIG. 1 is a front view of a television apparatus as an electronic apparatus according to a first embodiment;

FIG. 2 is a view showing a top surface of an inductor as an electronic component according to the first embodiment;

FIG. 3 is a view schematically showing a side surface of the inductor according to the first embodiment;

FIG. 4 is a view schematically showing another side surface of the inductor according to the first embodiment;

FIG. 5 is a view schematic showing the configuration of a bottom surface of the inductor according to the first embodiment;

FIG. 6 is a view schematic showing stress acting on the inductor according to the first embodiment due to thermal expansion;

FIG. 7 is a view in which an electronic component 4 as a first modification of a second embodiment is viewed from a bottom surface 141 side;

FIG. 8 is a view in which the electronic component 4 as the first modification of the second embodiment is viewed from a side surface 142 side;

FIG. 9 is a view in which an electronic component 4 as a second modification of the second embodiment is viewed from a side surface 141 side;

FIG. 10 is a view in which the electronic component 4 as the second modification of the second embodiment is viewed from a side surface 142 side;

FIG. 11 is a view in which an electronic component 4 as a first modification of a third embodiment is viewed from a side surface 141 side;

FIG. 12 is a view in which the electronic component 4 as the first modification of the third embodiment is viewed from a side surface 143 side;

FIG. 13 is a view in which an electronic component 4 as a second modification of the third embodiment is viewed from a side surface 141 side;

FIG. 14 is a view in which the electronic component 4 as the second modification of the third embodiment is viewed from a side surface 143 side;

FIG. 15 is a view in which an electronic component 4 as a fourth embodiment is viewed from a side surface 141 side;

FIG. 16 is a view showing a step for providing a protective layer 140 on a case 14 in an electronic component 4 according to a fifth embodiment;

FIG. 17 is a perspective view of a personal computer as an electronic apparatus according to a sixth embodiment; and

FIG. 18 is a perspective view of a magnetic disk device as an electronic apparatus according to a seventh embodiment.

### DETAILED DESCRIPTION

According to exemplary embodiments of the present invention, there is provided a television apparatus. The apparatus includes: an enclosure; a circuit board housed in the enclosure; and an electronic component mounted on the circuit board. The electronic component includes: a heating element that generates heat when current is supplied to the heating element; a housing that houses the heating element therein, the housing comprising: a first surface facing the circuit board; and a second surface opposite to the first surface; an electrode provided on the first surface of the housing and electrically connected to the circuit board; a bonding member provided on the first surface of the housing such that a position of the bonding member on the first surface does not overlap with a position of the electrode on the first surface, wherein the housing is bonded onto the circuit board via the bonding member; and a protective member provided between the first surface of the housing and the boding member so as to cover at least a partial region of the first surface of the housing, the protective member being configured to prevent the bonding member from entering into the first surface of the housing when the heating element generates heat.

Embodiments of the invention will be described below in detail with reference to the drawings. The following embodiments include similar constituent elements. Therefore, those similar constituent elements are referred to as the same numerals correspondingly, and redundant description thereof will be omitted in the following description.

### First Embodiment

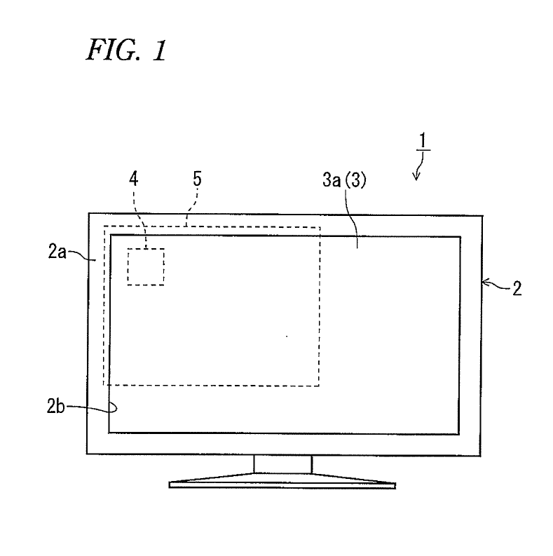

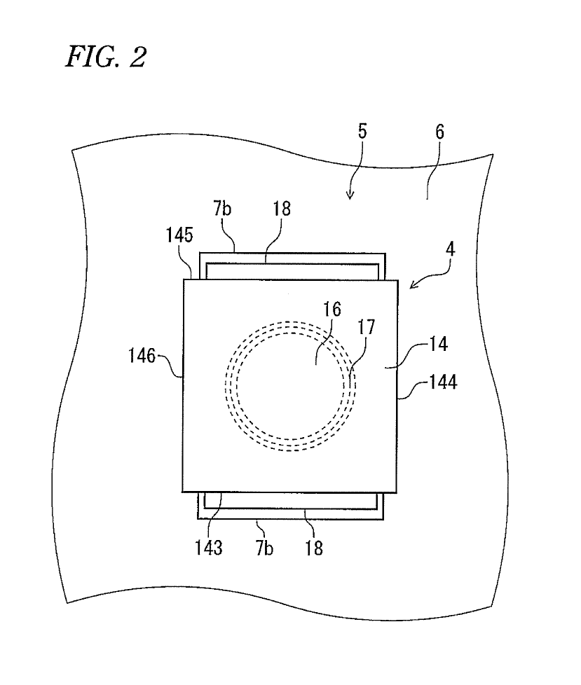

First, a first embodiment will be described with reference to FIGS. 1 to 3. As shown in FIG. 1, a television apparatus 1 as an electronic apparatus according to this embodiment has a rectangular (approximately rectangular) external appearance in front view seen from the front (display screen side) (in plan view with respect to the display screen). The television apparatus 1 has an enclosure 2, a display panel 3 (such as an LCD (Liquid Crystal Display)) as a display (display or display portion) with a display screen 3a exposed to the front (the outside) through an opening portion 2b provided in a front surface (front side or display screen side of the television apparatus) 2a of the enclosure 2, and a board 5 (such as a printed board, a circuit board, a printed wiring board, or a circuit substrate) mounted with an electronic component 4 (such as an inductor, a wiring component, a package, a heating element, an electronic component, a received component, a component, a device, a housing or a metal component) as an example of an electronic component (a structure, a component, a heating element, a heating component or an electronic component). The configuration of the electronic component 4 will be described later with reference to FIG. 2 et seq.

The display panel 3 and the board 5 are fixed to the enclosure 2 by not-shown screws (fixtures, fixing components, fixing units, support units, conducting components, conducting portions or mounting portions) or the like, so as to be partially electrically connected to the enclosure 2 (grounded or equalized in potential).

The display panel 3 is formed into a flat rectangular parallelepiped shape which is thin in the front/back direction (perpendicular to the paper of FIG. 1). The display panel 3 receives a video signal from a not-shown video signal processing circuit contained in a not-shown control circuit constituted by not-shown electronic components (circuit components) etc. mounted on the board 5, and displays a video image such as a still picture or a moving picture on the display screen 3a on the front surface side of the display panel 3. In addition to the video signal processing circuit, the control circuit of the television apparatus 1 includes a tuner, an HDMI (High-Definition Multimedia Interface) signal processor, an AV (Audio Video) input terminal, a remote controller signal receiver, a controller, a selector, an on-screen display interface, a storage (such as a ROM (Read Only Memory), a RAM (Random Access Memory) or an HDD (Hard Disk Drive)), an audio signal processing circuit, etc., all of which are not shown.

The board 5 is received at the rear (on the opposite side to the display screen) of the display panel 3 in the enclosure 2. In addition, the television apparatus 1 also includes an amplifier, speakers, etc. (not shown) for audio output.

As shown in FIG. 2, the board 5 is made of a material such as glass or epoxy resin, and has an insulating portion (insulating layer, resist layer, resist portion, etc.) 6 and a wiring pattern (wiring, pattern, non-conductive portion, conductive portion, signal line, etc.) 7. The wiring pattern 7 is formed of a conductor such as copper foil. The wiring pattern 7 is provided with a plurality of electrode pads (salient portions, plated portions, non-conductive portions, conductive portions, connecting portions, protrusions, etc.) 7b electrically connected to the wiring pattern 7 of the board 5.

Here, the electronic component 4 is a surface-mounted component. In this embodiment, for example, the electronic component 4 may include a winding component such as an inductor, a transformer, a coil or a filter. The electronic component 4 which will be described below by way of example has a simple configuration for the sake of simplification of description. However, the electronic component 4 in the embodiment is not limited to the simple configuration which will be described below, but the configuration of the embodiment may be applied to components, modules, etc., which are tied (fixed or attached) into the enclosure 2 by a bonding agent made of resin, including various winding components each provided with a large number of leads, chip components each having built-in silicon other than the winding components, or modules each having an outer shell made of a metal material.

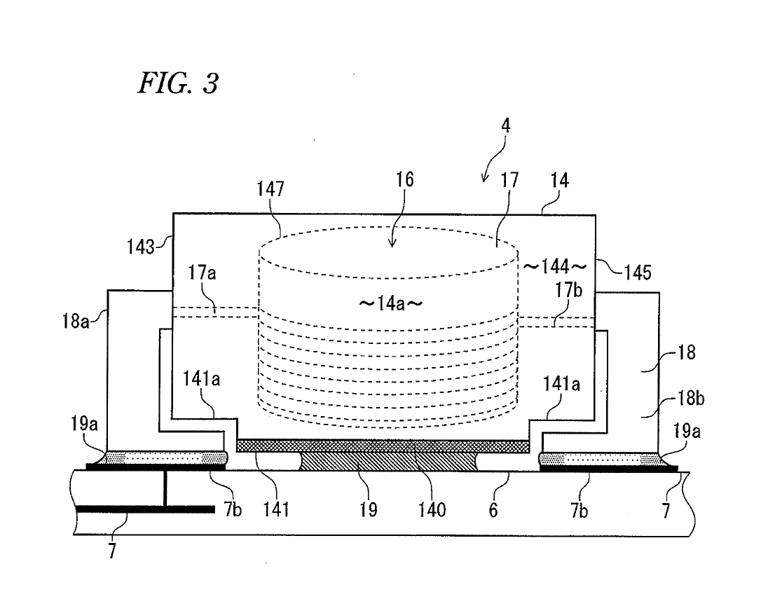

As shown in FIGS. 2 and 3, the electronic component 4 as an example is provided with a case (body, mold, enclosure, housing, reception portion, vessel portion, vessel, container portion, armor, metal portion, metal layer, heating portion, or heating element) 14, a conductor wire (wire portion, conducting portion, electric wire, heating portion, or heating element) 17 forming a core portion (central core portion, center portion, axial center portion, magnetic core portion, central portion, heating portion, or heating element) 16, and leads (connection portions) 18.

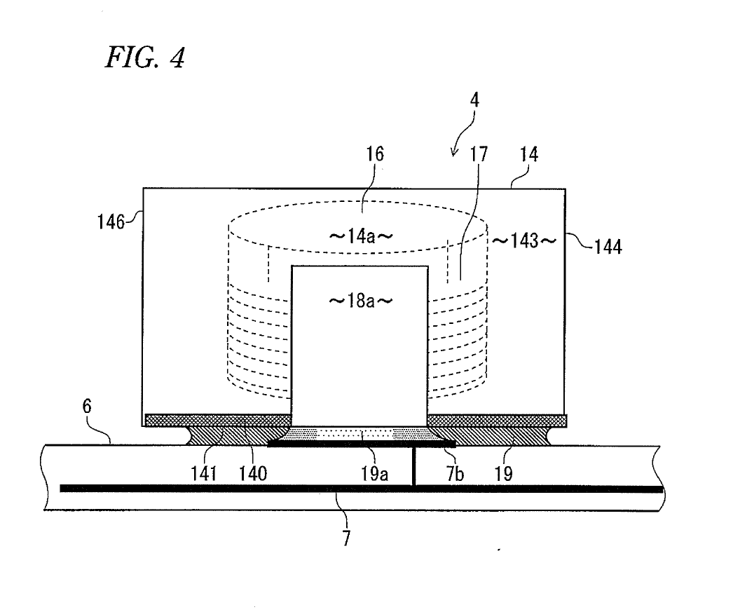

As shown in FIGS. 2 to 4, the case 14 is made of a material containing metal by way of example. The case 14 has a bottom surface (first surface, surface portion, wall portion, first wall, region, or bottom wall) 141 facing (opposed to or looking toward) the board 5, a top surface (second surface, surface portion, wall portion, second wall, region, or top wall) 142 located on the opposite side to the bottom surface 141, and side surfaces (third surfaces, surface portions, wall portions, third walls, regions, side walls, or side portions) 143, 144, 145 and 146 put between the bottom surface 141 and the top surface 142 (extending between the bottom surface 141 and the top surface 142 or provided on walls put between the bottom surface 141 and the top surface 142). The thickness of each of the walls constituting the bottom surface 141 and the top surface 142 is thinner than the thickness of each of the walls constituting the side surfaces 143, 144, 145 and 146 (the distance between the conductor wire 17 and the outer surface is shorter). This configuration contributes to reduction in profile, size and weight in the component, reduction in profile, size and weight in a module using the component, and reduction in profile, size and weight in an electronic apparatus having the built-in module.

As shown in FIG. 2, the core portion 16 serves as a path of magnetic flux. For example, the core portion 16 is formed by the conductor wire 17 wound in a cylindrical shape. The conductor wire 17 is, for example, a copper wire or an iron wire. The conductor wire 17 is not limited to the aforementioned examples, but any kind of material may be used to form the conductor wire 17 if the material can conduct electricity. As shown in FIG. 2, the conductor wire 17 has two terminal portions 17a and 17b extending away from the core portion 16. The terminal portions 17a and 17b can function as leads 18, as they are.

As shown in FIGS. 2 to 4, a plurality of leads 18 are provided. The leads 18 are provided to be received in an opening portion (recess portion or reception portion) 141a located in the bottom surface 141 of the case 14. The leads 18 have first and second terminal portions 18a and 18b protruding outward from the case 14. The first terminal portion 18a is a terminal portion which is soldered to a pad 7b provided on the board 5 so as to be electrically connected to the board 5. As shown in FIG. 2, the first terminal portion 18a, for example, extends toward the outside from the circumferential edge of the case 14 in view from the core portion 16.

As shown in FIG. 2, the second terminal portion 18b of the lead 18 is a terminal portion to which the terminal portion 17b of the conductor wire 17 is electrically connected. The terminal portion 17b of the conductor wire 17 is connected to the second terminal portion 18b of the lead 18 by use of a solder 19a by way of example.

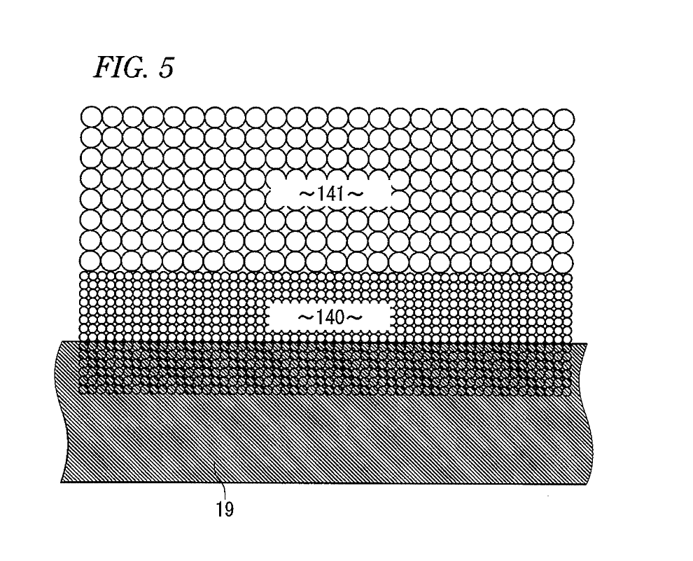

As shown in FIGS. 3 and 5, a protective layer (film, film portion, layer portion, layer, protective region, region, protective member, portion, seal portion, cover portion, or connection portion) 140 is provided on the bottom surface 141. The protective layer 140 is, for example, made from an insulating material containing silicon (high molecular compound, fine particles, or granulated powder) with a finer particle size (higher fluidity in a molten state) than the material (for example, iron powder) forming the case 14. In addition, the protective layer 140 has a higher coefficient of thermal expansion than the case 14 containing a metal material (the coefficient of expansion at the time of heating is different from that of the case 14).

As shown in FIGS. 3 and 5, a bonding member (bonding material, insulating member, adhesive material, resin material, or viscous material) 19 is located between the protective layer 140 and the board 5. The bonding member 19 is bonded with the protective layer 140 and the board 5. For example, the bonding member 19 is made of a resin material, and the coefficient of thermal expansion of the bonding member 19 is higher than that of the case 14 containing a metal material (the coefficient of expansion at the time of heating is different from that of the case 14).

In this manner, in the configuration of the embodiment, the protective layer 140 is provided on the bottom surface 141 of the electronic component 4 when the bonding member 19 is used to bond the electronic component 4 to the board 5. The protective layer 140 has a particle size finer than the material forming the case 14.

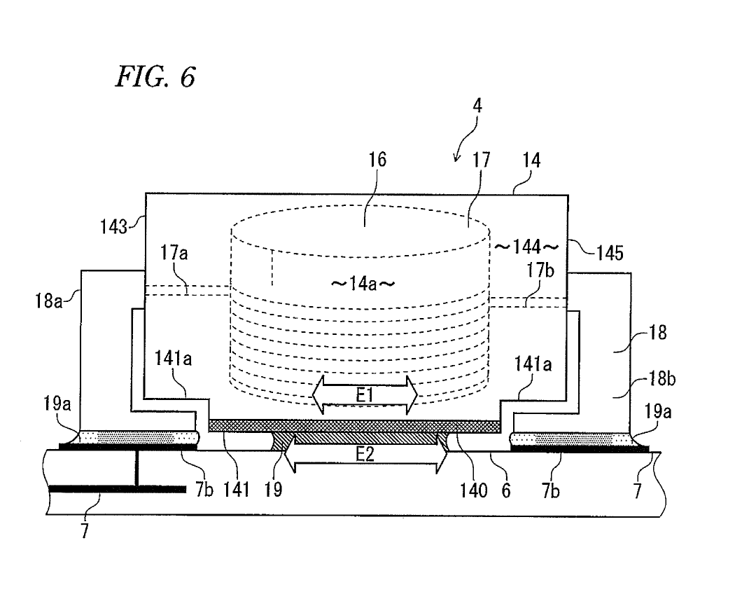

Here, the electronic component 4 is mounted on the board 5 by a reflow step. In the reflow step, the electronic component 4 is heated to a high temperature. The electronic component 4 is expanded and contracted due to the heat. As described above, the coefficient of thermal expansion of the case 14 made from metal is lower than that of the bonding member 19. Therefore, expansion E1 of the case 14 is smaller than expansion E2 of the bonding member 19 when the electronic component 4 is thermally expanded (see FIG. 6). Thus, mechanical stress, that is, tension is applied between the case 14 and the bonding member 19.

For example, when the bonding member 19 is attached (brought into contact, applied or bonded) directly to the case 14 so as to bond the board 5 with the case 14, the outside wall (surface or outer surface) of the case 14 is enlarged by the bonding member 19 due to the aforementioned tension as the tension grows to some extent. Thus, the region (surface) of the case 14 to which the bonding member 19 is attached is cracked so that there is a possibility that the bonding member 19 enters the case 14 through the cracks.

Particularly, assume that a metal composite type inductor component or the like, whose own weight is large, is mounted on a first surface side of the board 5. In this case, the bonding member 19 may be applied to the board 5 so as to temporarily fix the inductor component thereto in order to prevent the inductor component from dropping down due to its own weight at the time of reflowing on a second surface opposite to the first surface. However, such a component has a metal case in light of lower profile, higher robustness and higher manufacturability. Thus, the outside wall of the case may be often cracked due to the thermal expansion of the bonding member 19 at the time of the reflowing.

In the embodiment, therefore, the protective layer 140 is put in (at least a part of) the region between the bonding member 19 and the case 14 so as to reduce the bonding area between the bonding member 19 and the case 14. That is, direct bonding between the bonding member 19 and the case 14 is avoided or suppressed.

With this configuration, according to the embodiment, cracks in the region (surface) of the case 14 to which the bonding member 19 is attached is suppressed in the reflow step for mounting the component or when the bonding member 19 is expanded due to heat received from any peripheral heating component. It is therefore possible to reduce the possibility that the bonding member 19 enters the case 14 through the cracks. Thus, tolerance to stress on the electronic component 4 can be improved.

Here, description has been made along the example in which the electronic component 4 and the board 5 are bonded. However, the configuration of the embodiment can be applied to any component or material mounted in the state where members with different coefficients of thermal expansion are bonded with each other because the component or material may be cracked or damaged as described above.

### Second Embodiment

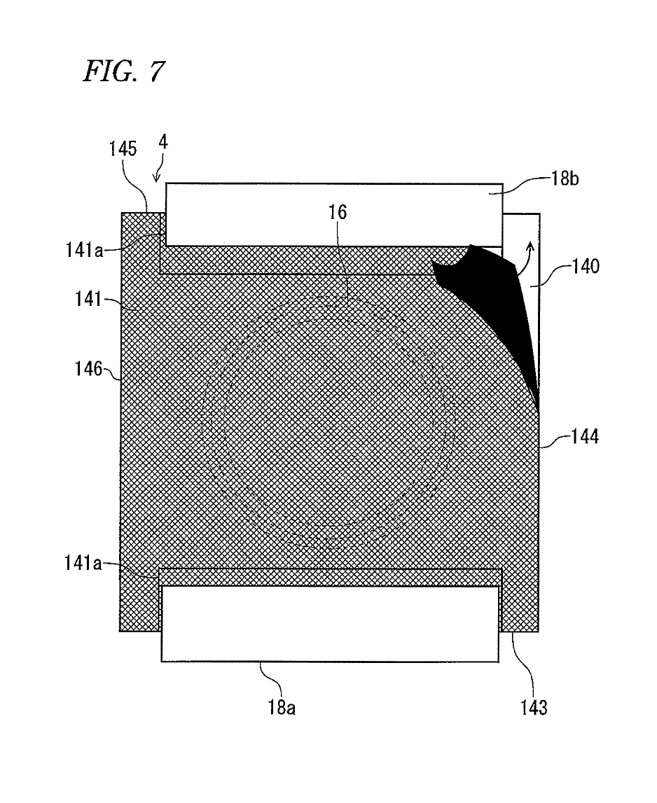

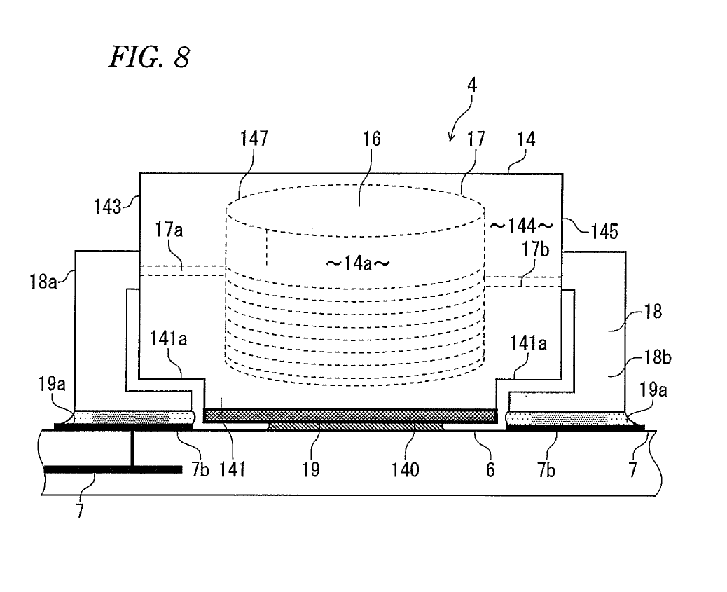

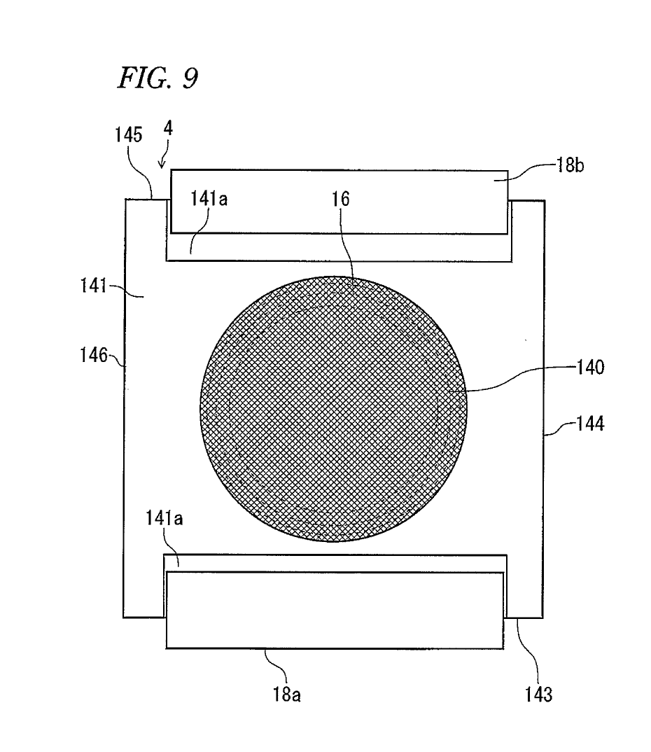

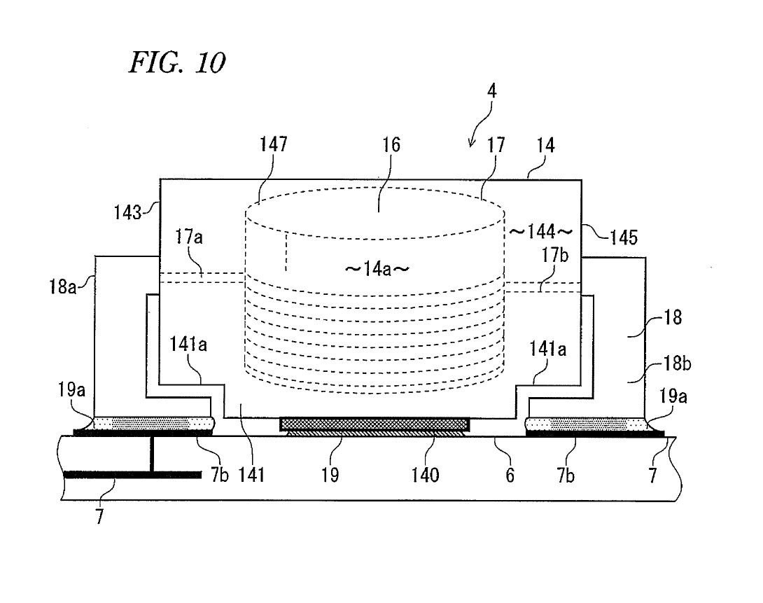

Next, a second embodiment will be described with reference to FIGS. 7 to 10. FIGS. 7 and 8 show a first modification of the second embodiment. FIGS. 9 and 10 show a second modification of the second embodiment. This embodiment is fundamentally the same as the first embodiment. Each modification of this embodiment is however different in the configuration of the protective layer 140 from the first embodiment. FIG. 7 is a view in which the electronic component 4 according to the first modification of the second embodiment is viewed from the bottom surface 141 side. FIG. 8 is a view in which the electronic component 4 according to the first modification of the second embodiment is viewed from the side surface 142 side. FIG. 9 is a view in which the electronic component 4 according to the second modification of the second embodiment is viewed from the bottom surface 141 side. FIG. 10 is a view in which the electronic component 4 according to the second modification of the second embodiment is viewed from the side surface 142 side.

As shown in FIGS. 7 and 8, the protective layer 140 in the first modification of the embodiment is made from a seal member which is pasted to the bottom surface 141 of the electronic component 4. As for the characteristic of the protective layer 140, the protective layer 140 has the same configuration as described above. That is, the material forming the protective layer 140 has a finer particle size than the material forming the case 14, and is put between the case 14 and the bonding member 19 so as to suppress stress on the case.

As shown in FIGS. 7 and 8, the protective layer 140 in the first modification of the embodiment is provided all over the bottom surface 141 of the electronic component 4. With this configuration, the whole of the bottom surface 141 of the electronic component 4 can be protected firmly.

On the other hand, as shown in FIGS. 9 and 10, the protective layer 140 in the second modification of the embodiment is provided in a partial region of the bottom surface 141 of the electronic component 4. This region is a region which is bonded with the bonding member 19. For example, when the bonding member 19 is provided like a solder ball not on the board 5 side but on the electronic component 4 side, the position to which the bonding member 19 should be applied can be clearly specified. Thus, the workability can be improved.

According to the aforementioned configuration, the electronic component 4 and the protective layer 140 can be managed as separate components. When there is a slight difference in coefficient of thermal expansion between the bonding member 19 and the case 14, the difference can be adjusted, for example, by suitable replacement of the protective layer 19 or the like.

As described above, also in this embodiment, the damage of the case 14 can be suppressed to contribute to improvement in tolerance to stress on the electronic component 4.

### Third Embodiment

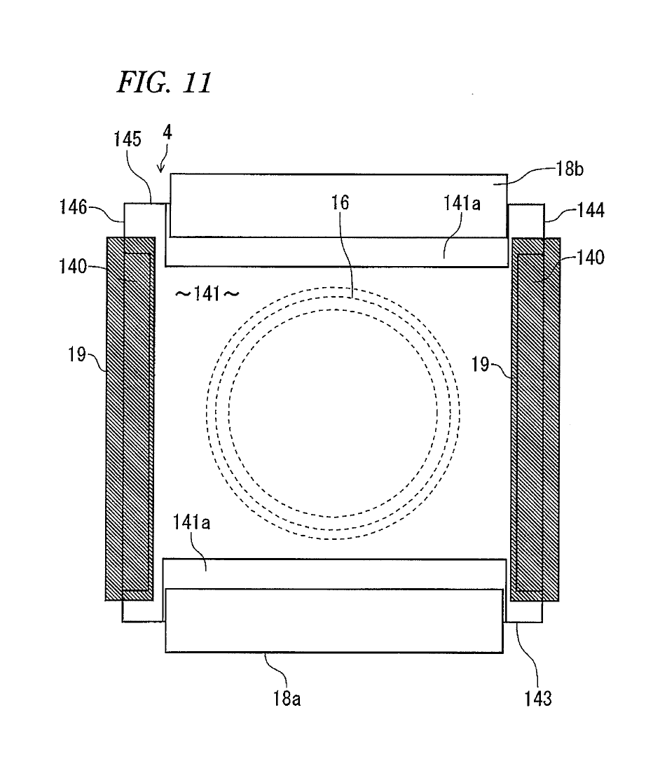

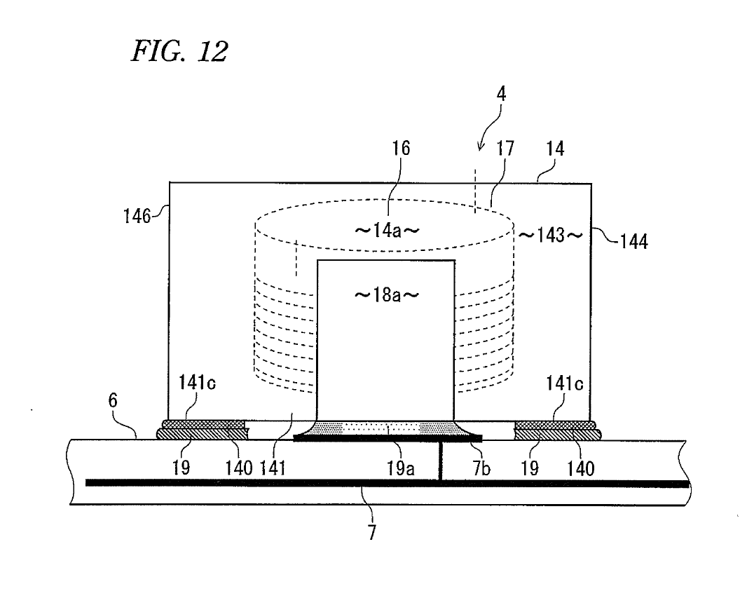

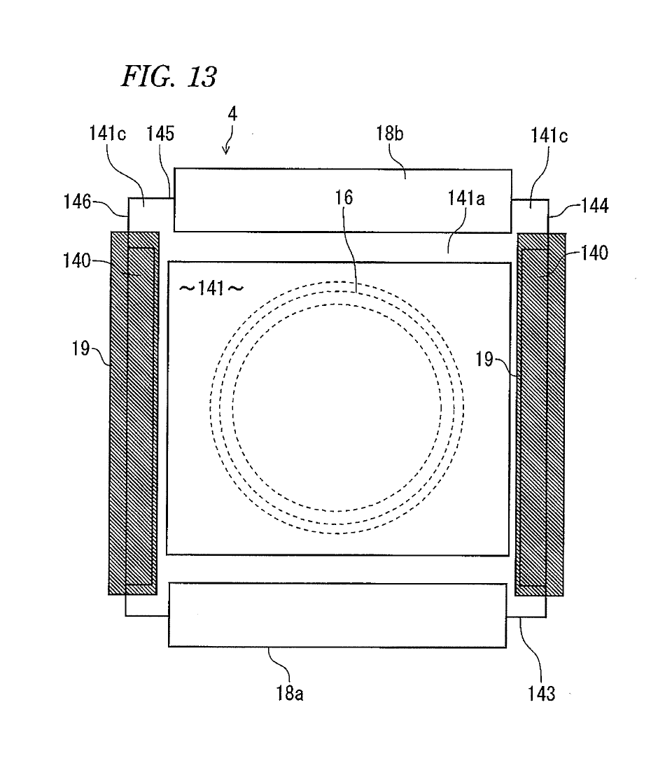

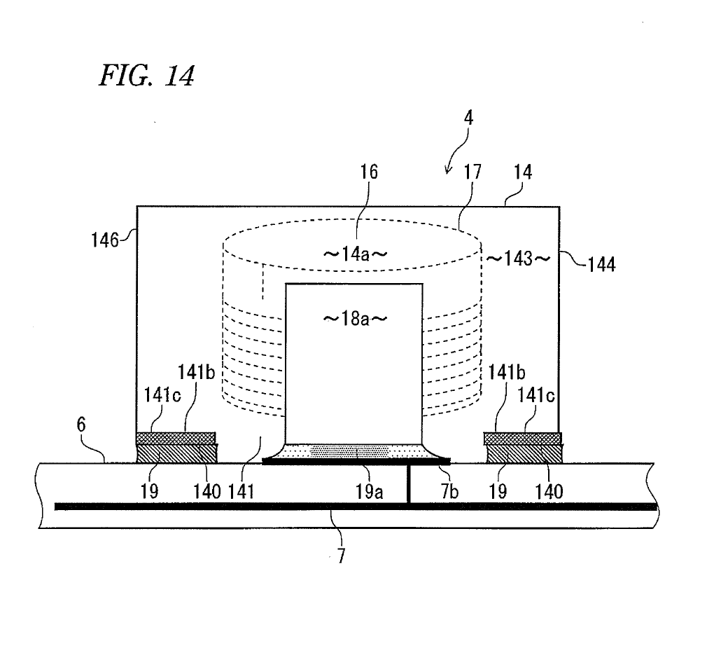

Next, a third embodiment will be described with reference to FIGS. 11 to 14. FIGS. 11 and 12 show a first modification of the third embodiment. FIGS. 13 and 14 show a second modification of the third embodiment. This embodiment is fundamentally the same as the first embodiment but different in the configuration of the bonding member 19 from each of the first and second embodiments. FIG. 11 is a view in which the electronic component 4 according to the first modification of the third embodiment is viewed from the bottom surface 141 side. FIG. 12 is a view in which the electronic component 4 according to the first modification of the third embodiment is viewed from the side surface 143 side. FIG. 13 is a view in which the electronic component 4 according to the second modification of the third embodiment is viewed from the bottom surface 141 side. FIG. 14 is a view in which the electronic component 4 according to the second modification of the third embodiment is viewed from the side surface 143 side.

As shown in FIGS. 11 to 14, the bonding member 19 according to each of the first and second modifications of the embodiment is located in an outer edge portion (edge portion, angled portion, corner portion, thick portion, end portion, or edge) 141c of the bottom surface 141 of the electronic component 4. In addition, at least a part of the protective layer 140 is also located in the outer edge portion 141c.

For example, the case 14 of the electronic component 4 may be formed into an angled cubic shape (approximately cubic shape) in light of manufacturability. As described above, walls constituting the case 14 are designed to be as thin as possible but thick enough to keep rigidity, in order to achieve a low profile structure. However, each corner portion where a side wall is connected to the bottom or top wall becomes thicker than any other flat portion. That is, even if the case 14 is cracked so that the bonding member 19 breaks through the protective layer 140, the entrance of the bonding member 19 into the case 14 can be suppressed as long as the crack is shallow. In addition, even if the bonding member 19 enters the outside edge portion 140c which is a corner portion, the influence can be comparatively reduced because the outside edge portion 140c is located away from the internal core portion 16.

In the second modification, as shown in FIGS. 13 and 14, an opening portion (recess portion, reception portion, region, or portion) 141b connected to the opening portion 141a is provided in the outside edge portion 141c of the case 14. The bonding member 19 and at least a part of the protective layer 140 are disposed in the opening portion 141b. With this configuration, a lower profile can be designed without changing the size of the core portion 16. In addition, outward protrusion of the protective layer 140 or the bonding member 19 liquefied by heat can be suppressed.

The configuration in which at least a part of the protective layer 140 is located in the outside edge portion 141c has been described here. However, damage due to occurrence of cracks can be reduced by the configuration in which the bonding member 19 is provided away from the thick portion/core portion 16 as described above. Thus, the protective layer 140 may be removed.

As described above, also in this embodiment, the damage of the case 14 can be suppressed to contribute to improvement in tolerance to stress on the electronic component 4.

### Fourth Embodiment

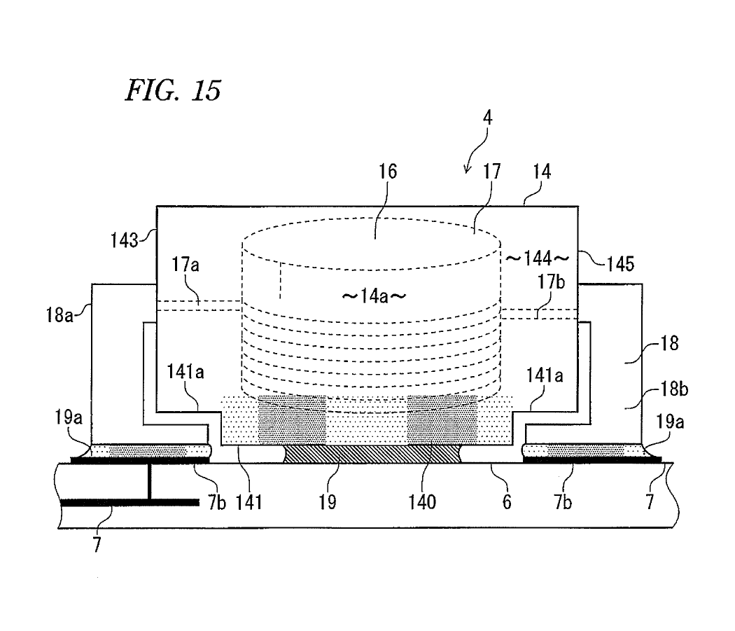

Next, a fourth embodiment will be described with reference to FIG. 15. This embodiment is fundamentally the same as the first embodiment, but different in the configuration of the case from the first embodiment. FIG. 15 is a sectional view of the electronic component 4 according to the fourth embodiment.

As shown in FIG. 15, in the case 14 according to this embodiment, the rigidity (particle concentration, grain concentration, or component) differs between the wall forming the top surface 142 and the wall forming the bottom surface 141. Specifically, the particle size of the wall forming the bottom surface 141 is finer than that of the wall forming the top surface 142. That is, the protective layer 140 is integrated with the bottom surface 141 of the case 14.

With this configuration, an effect similar to that of the first embodiment can be obtained.

Also in this embodiment, damage due to occurrence of cracks can be reduced so that the necessity of separately providing the protective layer 140 on the case 14 can be reduced. Thus, the protective layer 140 may be removed.

As described above, also in this embodiment, the damage of the case 14 can be suppressed to contribute to improvement in tolerance to stress on the electronic component 4.

### Fifth Embodiment

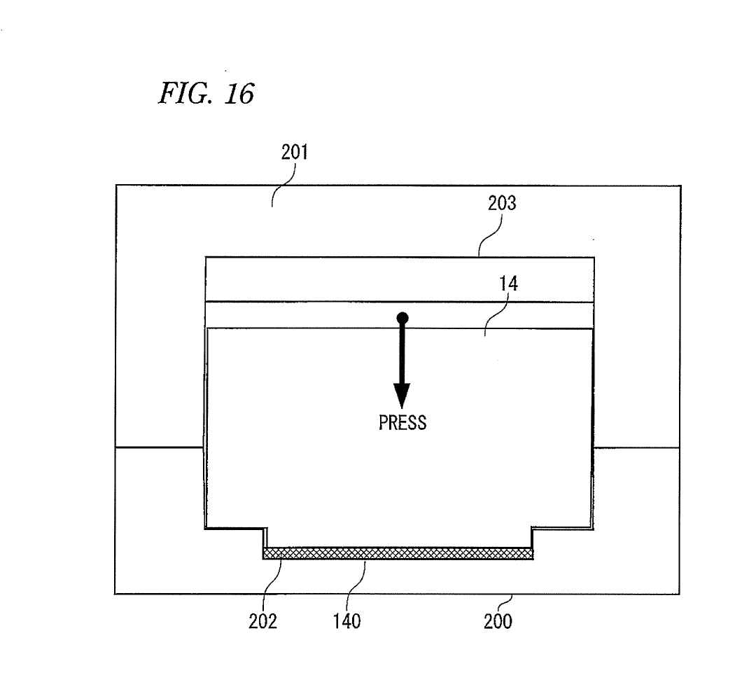

Next, a fifth embodiment will be described with reference to FIG. 16. This embodiment is fundamentally the same as the first embodiment but different from the first embodiment in terms of the configuration of the protective layer 140 provided on the case 14. FIG. 16 is a view showing the step in which the protective layer 140 is provided on the case 14 in the electronic component 4 according to the fifth embodiment.

As shown in FIG. 16, the case 14 according to the embodiment is manufactured with two molds 200 and 201. In the embodiment, cavities 202 and 203 as opening portions (recess portions) are provided in the molds 200 and 201. A powder material is buried into the cavities 202 and 203 and pressed by an inner lid. Alternatively, molten metal is poured into the cavities 202 and 203, and the two molds 200 and 201 are put on each other. An outer shell of the case 14 is formed thus.

Here, as shown in FIG. 16, a material serving as the protective layer 140 is applied into the cavity 202 of the mold 200 in advance.

With this configuration, the work to apply the protective layer 140 to the bottom surface 141 of the electronic component 4 or the work to paste a seal as shown in the second embodiment can be omitted.

### Sixth Embodiment

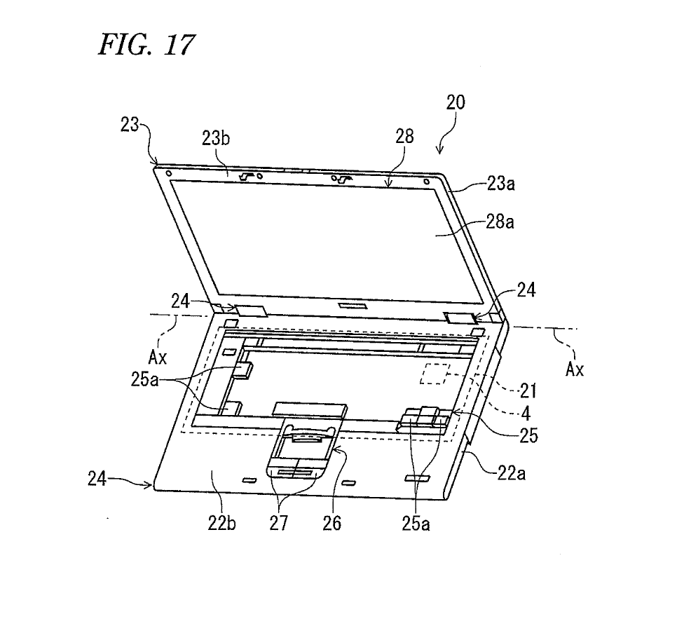

Next, a sixth embodiment will be described with reference to FIG. 17.

As shown in FIG. 17, an electronic apparatus according to this embodiment is configured as a so-called notebook type personal computer 20, which is provided with a rectangular and flat first body portion 22 and a rectangular and flat second body portion 23. The first and second body portions 22 and 23 are connected relatively rotatably around a rotation axis Ax with a hinge mechanism 24 so as to be put between an unfolded state shown in FIG. 5 and a not-shown folded state.

A keyboard 25, a pointing device 26, click buttons 27, etc. as input operation portions are provided in the first body portion 22 so as to be exposed on a front surface 22b serving as an outer surface of an enclosure 22a. On the other hand, a display panel 28 as a display (part) is provided in the second body portion 23 so as to be exposed on a front surface 23b serving as an outer surface of an enclosure 23a. The display panel 28 is, for example, configured as an LCD (Liquid Crystal Display). In the unfolded state of the personal computer 20, the keyboard 25, the pointing device 26, the click buttons 27, a display screen 28a of the display panel 28 are exposed so that a user can use them. On the other hand, in the folded state, the front surfaces 22b and 23b are close and opposite to each other so that the keyboard 25, the pointing device 26, the click buttons 27, the display panel 28, etc. can be hidden by the enclosures 22a and 23a. Here, keys 25a of the keyboard 25 are partially shown.

In the same manner as the board 5 shown in the first embodiment, a board 21 is received in the enclosure 22a of the first body portion 22 and/or the enclosure 23a of the second body portion 23 (only in the enclosure 22a in this embodiment).

The display panel 28 receives a display signal from a control circuit constituted by electronic components (circuit components) including an electronic component 4 etc. mounted on the board 21, and displays a video image such as a still picture or a moving picture. In addition, the control circuit of the personal computer 20 has a controller, a storage (such as a ROM (Read Only Memory), a RAM (Random Access Memory), an HDD (Hard Disk Drive), an interface circuit, various controllers, etc. In addition, speakers etc. (not shown) for audio output is also built in the personal computer 20.

The board 21 has a similar configuration to the board 5 in the first embodiment. The electronic component 4 is the electronic component 4 according to any one of the first to sixth embodiments. That is, the personal computer 20 as an electronic apparatus according to this embodiment includes the board 21 and the electronic component 4 as an electronic component structure mounted on the board 21. Accordingly, also in the personal computer 20 according to this embodiment, an effect similar to that obtained by the first to sixth embodiments can be obtained.

### Seventh Embodiment

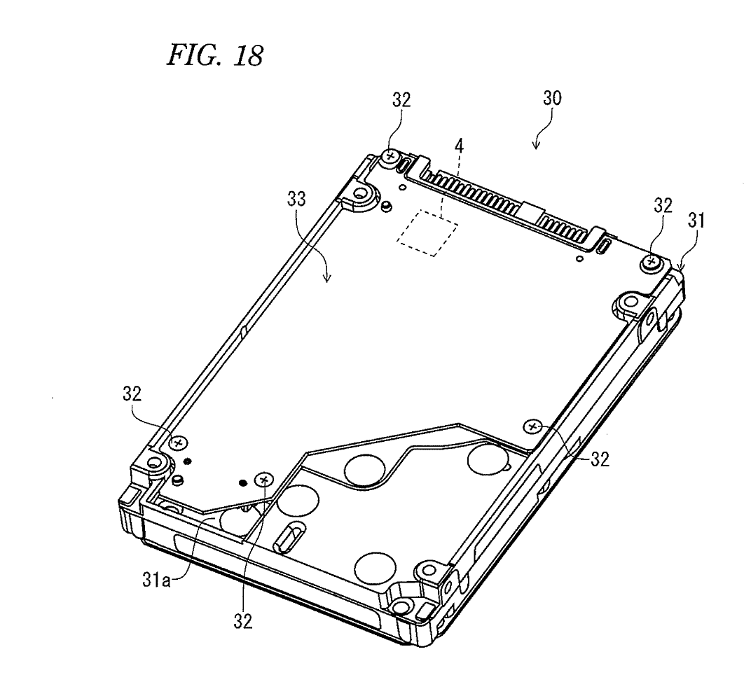

Next, a seventh embodiment will be described with reference to FIG. 18.

As shown in FIG. 18, an electronic apparatus according to this embodiment is configured as a magnetic disk device 30. The magnetic disk device 30 has a flat and rectangular parallelepiped enclosure 31 for receiving components including a magnetic disk (not shown), and a board (printed board) 33 attached to the enclosure 31 by fasteners such as screws 32.

In addition, the board 33 is disposed on an upper wall portion 31a of the enclosure 31. A film-like insulating sheet (not shown) is put between the board 33 and the upper wall portion 31a. In this embodiment, the back surface of the board 33 with respect to the line of sight, that is, the back surface (not shown) of the board 33 facing the upper wall portion 31a serves as a main mounting surface on which a plurality of electronic components including the electronic component 4 are mounted. Wiring patterns (not shown) are provided in the front surface and the back surface of the board 33. Not to say, electronic components may be also mounted on the front surface of the board 33.

Also in this embodiment, the board 33 has a similar configuration to that in the first embodiment, and the electronic component 4 mounted on the board 33 is the electronic component 4 according to any one of the first to sixth embodiments. That is, the magnetic disk device 30 as an electronic apparatus according to the embodiment has the board 33 and the electronic component 4 as an electronic component structure mounted on the board 33. Accordingly, also in the magnetic disk device 30 according to the embodiment, a similar effect to that obtained by any one of the first to sixth embodiments can be obtained.

As described above, according to the aforementioned embodiments, it is possible to provide an electronic component structure and the electronic apparatus in which electrodes can be well soldered to a board. Here, a television, a personal computer and a hard disk drive are shown as examples of the electronic apparatus. However, the invention is not limited to such apparatuses, but may be applied to any apparatus in the whole field of digital products if the apparatus drives a circuit constituted by electronic components (circuit components) including the electronic component 4.

While certain embodiments have been described, these embodiments have been presented by way of example only, and are not intended to limit the scope of the invention. Indeed, the novel methods and systems described herein may be embodied in a variety of other forms. Furthermore, various omissions, substitutions and changes in the form of the methods and systems described herein may be made without departing from the sprit of the invention. The accompanying claims and their equivalents are intended to cover such forms or modifications as would fall within the scope and sprit of the invention.

What is claimed is:

1. A television apparatus comprising:
an enclosure;
a circuit board housed in the enclosure; and
an electronic component mounted on the circuit board, the electronic component comprising:
a heating element that generates heat when current is supplied to the heating element;
a housing that houses the heating element therein, the housing comprising: a first surface facing the circuit board; and a second surface opposite to the first surface;
an electrode provided on the first surface of the housing and electrically connected to the circuit board;
a bonding member provided on the first surface of the housing such that a position of the bonding member on the first surface does not overlap with a position of the electrode on the first surface, wherein the housing is bonded onto the circuit board via the bonding member; and
a protective member provided between the first surface of the housing and the boding member so as to cover at least a partial region of the first surface of the housing, the protective member being configured to prevent the bonding member from entering into the first surface of the housing when the heating element generates heat.

2. The apparatus of claim 1, wherein
the housing is made of a material containing metal, and
the bonding member is made of a resin material.

3. The apparatus of claim 2, wherein the protective member is an insulating material coated on the first surface of the housing.

4. The apparatus of claim 3, wherein the protective member faces the heating element.

5. The apparatus of claim 3, wherein the protective member is provided along a periphery of the housing.

6. The apparatus of claim 3, wherein
the protective member is made of a granular material containing a high molecular compound, and is not electrically connected to a surface portion of the circuit board.

7. The apparatus of claim 3, wherein the protective member is a layer of particles whose fluidity is higher than that of a material of the housing.

8. The apparatus of claim 3, wherein the protective member is made of a silicon material.

9. An electronic apparatus comprising:
an enclosure;
a circuit board housed in the enclosure;
a component comprising:
a first surface, wherein an electrode is provided on the first surface and electrically connected to the circuit board; and
a second surface opposite to the first surface,
a bonding material, wherein the component and the circuit board are bonded to each other via the bonding material; and
a protective member, at least a part of which is provided between the bonding material and the first surface of the component such that a position of the at least a part of the protective member does not overlap with a position of the electrode.

10. The apparatus of claim 9, wherein:
the protective member is made of a granular material containing a high molecular compound, and is not electrically connected to a surface portion of the circuit board.
